(19) United States
(12) Patent Application Publication
(10) Pub. No.: US 2025/0318331 A1
(43) Pub. Date: Oct. 9, 2025

(54) OPTOELECTRONIC DEVICE AND METHOD FOR MANUFACTURING AN OPTOELECTRONIC DEVICE

(71) Applicant: ams-OSRAM International GmbH, Regensburg (DE)

(72) Inventors: Simon Jerebic, Donaustauf (DE); Markus Klein, Regensburg (DE); Michael Betz, Bodenkirchen (DE)

(21) Appl. No.: 18/866,000

(22) PCT Filed: May 10, 2023
(86) PCT No.: PCT/EP2023/062459

§ 371 Date: Nov. 14, 2024

(30) Foreign Application Priority Data
May 18, 2022 (DE) 10 2022 112 418.5

(51) Int. Cl. H10H 20/853; H10H 20/01; H10H 20/85; H10H 20/851; H10H 20/854

(52) U.S. Cl. CPC H10H 20/853; H10H 20/0361; H10H 20/0362; H10H 20/8508; H10H 20/8515; H10H 20/8516; H10H 20/854

(57) ABSTRACT

In an embodiment a device includes a carrier substrate with a first contact region and therefrom electrically insulated a second contact region, a light-emitting component arranged on the carrier substrate and electrically coupled to the first and second contact regions, a reflective encapsulation arranged on the carrier substrate, wherein the reflective encapsulation surrounds the light-emitting component and forms a cavity above a light-emitting surface of the light-emitting component, and a light conversion layer arranged directly on the light-emitting component in the cavity, wherein the light-emitting surface is smaller than a top surface of the light-emitting component, wherein the light conversion layer is substantially congruent with the light-emitting surface, wherein the cavity has a bottom lying in the same plane as the light-emitting surface, and wherein the cavity has side surfaces which are arranged at least partially at a distance from the light conversion layer so that a gap exists between the light conversion layer and the reflective encapsulation.

### CROSS-REFERENCE TO RELATED APPLICATIONS

This patent application is a national phase filing under section 371 of PCT/EP2023/062459, filed May 10, 2023, which claims the priority of German patent application no. 10 2022 112 418.5, filed May 18, 2022, each of which is incorporated herein by reference in its entirety.

### TECHNICAL FIELD

The present invention relates to an optoelectronic device and a method for manufacturing an optoelectronic device.

### BACKGROUND

In the manufacture of optoelectronic devices, in particular LED packages comprising a conversion layer for converting light from blue light into white light, for example, there is currently the problem that:

known options for applying a conversion layer to an LED chip do not provide the desired efficiency in terms of converting the light;

the optoelectronic device is not sufficiently robust against external mechanical and chemical influences; and/or

the thermal and electrical connection of the LED chip to a printed circuit board, for example, is not optimal, as an optimal connection would usually require high temperatures at a time when the conversion layer has already been applied to the LED chip, but the conversion layer would be damaged by the high temperatures.

In addition, options that attempt to improve at least one of the aforementioned problems currently require complex production concepts and process flows and thus cause high process costs (e.g. due to complex sequential processes or auxiliary processes) and therefore high product costs.

### SUMMARY

Embodiments provide an optoelectronic device and a method for manufacturing an optoelectronic device which counteracts at least one of the aforementioned problems.

Embodiments suggest to arrange a conversion layer very closely, precisely and without an adhesive joint over the light-generating epitaxial layer of a light-emitting chip, and to arrange the conversion layer on the chip only at a time after the chip has been applied to a carrier substrate, such as a lead frame or a printed circuit board. This increases the efficiency of the light conversion, since the conversion material of the conversion layer is limited to the area of the light-generating epitaxial layer or the light-emitting surface of the chip, thus reducing losses at the edges of the light-emitting surface, and since the elimination of an adhesive layer also reduces outcoupling losses. The light conversion layer is therefore arranged directly on the light-emitting surface of the chip without an adhesive. In addition, the thermal and electrical bonding of the chip to the carrier substrate can be increased, as the bonding takes place at a time when the conversion layer is not yet arranged on the chip and therefore higher temperatures can be used.

According to a first embodiment, the chip is arranged on a carrier substrate, such as a lead frame or a printed circuit board, electrically connected and then encapsulated with a reflective encapsulation material. In particular, the carrier substrate already forms the final substrate on which the chip is also arranged in the final device. During the encapsulation step, the chip is enclosed laterally by the encapsulation material and thus protected by the encapsulation. In addition, the tool for encapsulating the chip is designed in such a way that the encapsulation material protrudes above the chip in the vertical direction and a cavity is formed above the light-generating epitaxial layer or the light-emitting surface of the chip, which exposes at least the light-emitting surface. For example, the light-emitting surface of the semiconductor chip can be smaller than the top surface of the semiconductor chip and thus only extend over part of the top surface of the semiconductor chip, but it is also possible for the light-emitting surface of the semiconductor chip to extend over the entire top surface of the semiconductor chip.

Since the encapsulation step is a relatively imprecise process for creating a cavity that is essentially congruent with the light-emitting surface in terms of both size and position, the cavity can be deliberately chosen to be larger than the light-emitting surface so that, despite manufacturing tolerances, the light-emitting surface lies completely within the cavity and is not covered by the encapsulation material.

However, due to the manufacturing tolerances and the larger dimensions of the cavity in particular, the exact position of the light-emitting surface in relation to the cavity is not known exactly and can vary from device to device. In a further step, the position of the light-emitting surface in relation to the cavity is therefore determined. This can be done using very precise optical methods, either in a state in which the chip emits light through the light-emitting surface or in a state in which the chip emits no light. The known position of the light-emitting surface relative to the cavity can then be used to structure a photosensitive material introduced into the cavity, namely in such a way that the photosensitive material comprises an opening essentially congruent with the light-emitting surface.

Compared to the encapsulation step, the step of structuring the photosensitive material is a relatively precise process for creating an opening or cavity. By means of the photosensitive material and the structuring of the photosensitive material, a relatively precisely positioned and precisely dimensioned opening in relation to the light-emitting surface can thus be created in the relatively imprecisely positioned and “oversized” cavity in the encapsulation material in a subsequent step. The step of structuring the photosensitive material or, in particular, exposing the photosensitive material to light to open the photosensitive material in a desired area can be carried out using an external/separate light source, but it is also conceivable that the photosensitive material is opened above the light-emitting surface by means of the light-emitting component of the optoelectronic device itself.

The resulting opening in the photosensitive material then serves as a template or mask to create a light conversion layer very closely, precisely and without an adhesive gap over the light-emitting surface directly on the chip. For this purpose, the opening is filled with a light-converting material, for example a matrix material comprising light-converting particles, and the material is cured.

The remaining photosensitive material can then be removed and the resulting gap between the reflective encapsulant and the light conversion layer can be filled with a reflective encapsulant to further increase the outcoupling efficiency and light conversion efficiency.

According to a further embodiment, the chip is arranged on a carrier substrate, such as a lead frame or a printed circuit board, electrically connected and the position of the light-emitting surface of the chip is determined opposite or in relation to the carrier substrate. This can be done using very precise optical methods, either in a state in which the chip emits light through the light-emitting surface or in a state in which the chip emits no light. Determining the position may be necessary, for example, because the arrangement of the chip on the carrier substrate may be relatively imprecise due to positioning tolerances, so that the position of the light-emitting surface in relation to the carrier substrate may only be known with relative imprecision.

The position of the light-emitting surface relative to the carrier substrate known by the determination can then be used to structure a photosensitive material applied to the chip and optionally also to the carrier substrate, namely in such a way that the photosensitive material remains essentially congruent with the light-emitting surface on the light-emitting surface and areas of the photosensitive material that are not congruent with the light-emitting surface are removed. By determining the position of the light-emitting surface in combination with the step of structuring the photosensitive material, the photosensitive material can thus be structured by means of a simple but relatively precise process in such a way that it remains relatively precisely positioned and precisely dimensioned essentially congruently on the light-emitting surface.

The step of structuring the photosensitive material or, in particular, exposing the photosensitive material in a desired area can be carried out with an external/separate light source, but it is also conceivable that the photosensitive material is exposed above the light-emitting surface by means of the light-emitting component itself.

Alternatively, it is possible for the photosensitive material to be applied or structured to the light-emitting surface at a precise position at a time when the chip is still in the wafer compound, i.e. on the growth wafer or manufacturing substrate of the chip. Determining the position of the light-emitting surface of the chip by means of a separate optical process can be omitted in such a case, since the exact position of the light-emitting surface of the chip in relation to the growth substrate can already be known due to the production on the same substrate or can be easily determined without a separate optical process. Accordingly, the photosensitive material can already be precisely positioned in advance on the light-emitting surface of the chip without the need for a further optical process to determine the position of the light-emitting surface at a later time.

The photosensitive material arranged on the light-emitting surface and essentially congruent with the light-emitting surface can also serve as a placeholder for a light conversion layer, which is formed on the light-emitting surface at a later point in time instead of the photosensitive material. For this purpose, the chip is encapsulated on the carrier substrate with the photosensitive material arranged on the chip using a reflective encapsulation material. During the encapsulation step, the chip and the photosensitive material are enclosed laterally by the encapsulation material and thus protected by the encapsulation. The encapsulation material can be essentially flush with the photosensitive material on a surface opposite the carrier substrate, or a cavity can be formed above the photosensitive material by means of a corresponding tool for encapsulating the chip in such a way that the encapsulation material protrudes above the chip and the photosensitive material in the vertical direction and a cavity is formed above the photosensitive material, which at least exposes the photosensitive material.

The photosensitive material as a precisely positioned placeholder for the subsequent light conversion layer can be used in a relatively imprecise process, such as encapsulating the chip on the carrier substrate with the reflective encapsulation material, to form a precisely positioned cavity in the reflective encapsulation, which can then be filled with a light conversion material to form the light conversion layer. For this purpose, after encapsulating the chip on the carrier substrate and curing the reflective encapsulation material, the photosensitive material on the light-emitting surface is removed, and the resulting cavity in the reflective encapsulation serves as a template or mask to create a light conversion layer very closely, precisely and without an adhesive joint over the light-emitting surface directly on the chip. For this purpose, the cavity is filled with a light-converting material, for example a matrix material comprising light-converting particles, and the material is cured.

The package resulting from the steps described in the various embodiments protects all sensitive elements of the device and is therefore mechanically very robust. It can also be manufactured cost-effectively due to the large proportion of parallelizable processes, and an increase in brightness of the optoelectronic device can be achieved compared to conventional similar devices.

The optoelectronic device combines the features:

Precisely defined position and low thickness of a conversion layer possible, as well as no need for an adhesive joint (compared to a so-called layer attach process or other alternative approaches);

Realization of a conversion layer at a late stage in the manufacturing process (compared to processes in which a light conversion layer is applied to a chip at a time when the chip is still in the wafer compound) and the associated advantages;

Realizability of a conversion layer without the use of a temporary carrier and the associated advantages, since the step of applying the conversion layer is carried out when the chip is already deposited on the final carrier substrate.

According to at least one embodiment, an optoelectronic device comprises a carrier substrate having a first contact region and a second contact region electrically insulated therefrom, and a light-emitting component which is arranged on the carrier substrate and is electrically coupled to the first and second contact regions. In addition, a reflective encapsulation is arranged on the carrier substrate, which surrounds the light-emitting component in the lateral direction, which projects above the light-emitting component in the vertical direction, and which forms a cavity above a light-emitting surface of the light-emitting component. In the cavity, a light conversion layer is arranged on the light-emitting component, which in a plan view of the light-emitting surface is essentially congruent with the light-emitting surface. The formed cavity comprises a bottom which lies in the same plane as the light-emitting surface, and the formed cavity comprises side surfaces which are arranged at least partially at a distance from the light conversion layer, so that there is a gap between the light conversion layer and the reflective encapsulation.

The light conversion layer can, for example, be a layer comprising a matrix material with light conversion particles located therein, which are designed to convert light of a first wavelength emitted by the light-emitting component, which impinges on the light conversion particles, into light of a second wavelength different from the first. The light conversion particles can, for example, be so-called phosphors or phosphors. The matrix material can be a silicone, for example.

The reflective encapsulation or the reflective encapsulation material can, for example, be a white encapsulation or a white encapsulation material.

According to at least one embodiment, the bottom of the cavity formed is larger than the light-emitting surface in a plan view of the light-emitting surface. In particular, the bottom of the cavity is larger than the light-emitting surface and is arranged opposite the light-emitting surface in such a way that the light-emitting surface remains free of the reflective encapsulation.

According to at least one embodiment, a distance from a first side surface of the cavity to a first edge of the light-emitting surface closest to the first side surface is greater than a distance from a second side surface of the cavity to a second edge of the light-emitting surface closest to the second side surface. The bottom or the base surface of the cavity can accordingly be arranged off-center or not symmetrically relative to the center of gravity of the light-emitting surface.

According to at least one embodiment, a distance between opposite side surfaces of the cavity decreases from a side of the reflective encapsulation opposite the carrier substrate towards the bottom of the cavity. The side surfaces of the cavity are accordingly inclined relative to the light-emitting surface or the side of the reflective encapsulation opposite the carrier substrate, in particular by an angle of between 0° and 90°, so that the cavity tapers in the direction of the light-emitting surface. This can be caused in particular by the fact that a tool/die for forming the cavity can have mold chamfers for demolding the cavity. However, it is also possible that a desired radiation characteristic of the optoelectronic device is achieved via the inclination of the side surfaces.

According to at least one embodiment, the optoelectronic device further comprises a mold material which is arranged in the cavity in the gap between the reflective encapsulation and the light conversion layer, and in particular fills the gap. The mold material may be, for example, a TiO₂ silicone which is placed in the gap and which is adapted to reflect a light emitted from the light-emitting component and light converted by the conversion layer in the direction of a main emission direction of the optoelectronic device.

According to at least one embodiment, a top surface of the light conversion layer is substantially flush with a side of the reflective encapsulation opposite the carrier substrate. The light conversion layer may accordingly comprise a thickness such that it is planar in the vertical direction with the reflective encapsulation. Such planarity can be achieved, for example, by precisely selecting the amount of light-converting material introduced into the opening to produce the light-conversion layer so that the light-converting material fills the opening exactly, or the planarity can be achieved by grinding off the light-conversion layer and/or the reflective encapsulation.

According to at least one embodiment, the light conversion layer comprises an increasing concentration gradient of light conversion particles arranged in the light conversion layer from a top surface of the light conversion layer towards the light-emitting component. A large proportion of the light conversion particles in the light conversion layer can accordingly be located in an area of the light conversion layer close to the light-emitting surface, whereas an area of the light conversion layer further away from the light-emitting surface can comprise a lower concentration of light conversion particles. On the one hand, this allows an increased efficiency of the light conversion to be achieved, and the optoelectronic device can be ground down without risking a change in color location, as there are no or hardly any light conversion particles on the top surface of the light conversion layer that could be torn out when the top surface is ground down.

The light-emitting component can be an LED chip that is designed to emit light of a specific wavelength. In particular, the light-emitting component can be an LED chip pre-sorted according to the emitted wavelength, which is designed to emit blue light, for example.

The light-emitting component can, for example, comprise a light-emitting surface with a size in the range of 0.5 mm² to 2 mm², for example 1 mm², and a height of 80 μm to 200 μm, in particular up to 120 μm. The edge length of such a light-emitting component can, for example, be in the range between 10 μm and 50 μm.

According to at least one embodiment, the light-emitting component is formed by a flip chip. The flip chip can have electrical connection surfaces on the same side, namely the underside of the chip. The electrical connection surfaces on the underside can be arranged on the first or second contact region and electrically connected to it. In particular, the reflective encapsulation can be formed only slightly higher than the chip on the carrier substrate, resulting in a depth for the cavity that correlates with a desired thickness of the conversion layer.

According to at least one embodiment, the light-emitting component is electrically coupled to the second contact region by means of a bonding wire, and the bonding wire is completely enclosed by the reflective encapsulation. The light-emitting component can, for example, be formed by a top contact chip, which comprises an electrical connection surface on its underside and an electrical connection surface on a top surface of the chip opposite the underside. The electrical connection surface on the bottom surface can be arranged on the first contact region and electrically connected to it, and the electrical connection surface on the top side can be electrically coupled to the second contact region by means of a bonding wire. In particular, the reflective encapsulation can be formed at least high enough on the carrier substrate so that the bonding wire is completely covered by the encapsulation material. Due to the resulting height of the reflective encapsulation, the cavity can have a height that is greater than when a flip chip is used. Due to the height of the cavity, it may therefore be desirable for the light conversion layer to have an increasing concentration gradient of light conversion particles arranged in the light conversion layer towards the light-emitting component, so that a dense phosphor packing of light conversion particles close to the epi is formed in the light conversion layer.

A method of manufacturing an optoelectronic device is also proposed. The method comprises the following steps:

Providing a carrier substrate with at least one light-emitting component arranged thereon which comprises a light-emitting surface;

Determining the position of the light-emitting surface;

Arranging and structuring a photosensitive material in such a way that an opening in the photosensitive material is substantially congruent with the light-emitting surface in a plan view of the light-emitting surface, or that the photosensitive material is substantially congruent with the light-emitting surface on the light-emitting surface in a plan view of the light-emitting surface;

Encapsulating the at least one light-emitting component on the carrier substrate with a reflective encapsulation material in such a way that

the at least one light-emitting component is surrounded in the lateral direction by the reflective encapsulation material,

the reflective encapsulation material projects vertically beyond the at least one light-emitting component, and

the reflective encapsulation material forms a cavity above a light-emitting surface of the at least one light-emitting component, which comprises a bottom that lies in the same plane as the light-emitting surface;

and

Creating a light conversion layer in the cavity on the light-emitting surface in such a way that the light conversion layer is essentially congruent with the light-emitting surface on the light-emitting surface in a plan view of the light-emitting surface.

The steps of arranging and structuring the photosensitive material can include, in particular, common photolithography processes as well as nanoimprint, laser and etching processes to produce the desired structuring in a photosensitive material.

According to at least one embodiment, the method further comprises removing the photosensitive material after the at least one light-emitting component has been encapsulated on the carrier substrate with the reflective encapsulating material so that a positionally accurate cavity is formed in the encapsulating material above the light-emitting surface. The step of creating the light conversion layer can then take place after the step of removing the photosensitive material in the precisely positioned cavity.

According to at least one embodiment, the step of arranging and structuring the photosensitive material takes place after the step of encapsulating the at least one light-emitting component in the cavity formed in the reflective first encapsulation material. The cavity formed has, in particular, side surfaces which are arranged at least partially at a distance from the light-emitting surface and thus from the light conversion layer, and the photosensitive material is arranged and structured in particular in such a way that an opening in the photosensitive material is essentially congruent with the light-emitting surface in a plan view of the light-emitting surface. The light conversion layer is then created in the opening so that a gap between the light conversion layer and the reflective encapsulation material is filled with the photosensitive material.

According to at least one embodiment, however, the step of arranging and structuring the photosensitive material takes place before the step of encapsulating the at least one light-emitting component. In particular, the step of arranging and structuring the photosensitive material is carried out in such a way that the photosensitive material is essentially congruent with the light-emitting surface on the light-emitting surface in a plan view of the light-emitting surface. The light-emitting component is then encapsulated on the carrier substrate with the reflective encapsulation material in such a way that the at least one light-emitting component and the photosensitive material on the light-emitting surface are surrounded in the lateral direction by the reflective encapsulation material, the reflective encapsulation material projects above the at least one light-emitting component in the vertical direction, and the reflective encapsulation material forms a cavity above the light-emitting surface of the at least one light-emitting component, which cavity is filled with the photosensitive material. The photosensitive material in the cavity is then removed and a light conversion layer can be formed in the cavity that is essentially congruent with the light-emitting surface.

The step of creating the light conversion layer in the cavity of the reflective encapsulation material or in the opening of the photosensitive material can include filling the opening with a light-converting material. Filling with the light-converting material can be done, for example, by squeegeeing, printing, jetting, dispensing or spraying.

According to at least one embodiment, the step of creating the light conversion layer also comprises curing or heating the light-converting material so that it is stable in itself on the one hand and forms a fixed connection with the at least one light-emitting component on the other. The resulting conversion layer can accordingly comprise a fixed connection with the at least one light-emitting component.

According to at least one embodiment, the step of encapsulating the at least one light-emitting component comprises a film-assisted molding step. Film-assisted molding (FAM) is a variant of transfer molding. In film-assisted molding, plastic films are used in a mold and these are sucked into the inner surfaces of the mold (sprues, cavities and gates) under vacuum before the products to be encapsulated are inserted into the mold. This is followed by an overmolding or encapsulation process. The molding compound is first liquefied by heat and pressure, then pressed into closed mold cavities and held there under further heat and pressure until the entire material has solidified (i.e. hardened). After opening the mold, the encapsulated products are removed. Film-assisted molding offers a number of advantages over conventional transfer molding. These include the simple demolding of the encapsulated products and the fact that metal surfaces of the mold can be kept free of sticky molding compound. Another advantage is that the film acts as protection, which leads to less wear on the molded parts, i.e. a longer service life. It is also possible to produce more delicate and closely spaced structures using FAM or to demold them cleanly.

According to at least one embodiment, the method further comprises removing the photosensitive material in the gap between the reflective encapsulant material and the light conversion layer. The gap between the reflective encapsulation material and the light conversion layer and in particular the final optoelectronic device may accordingly be free of the photosensitive material.

According to at least one embodiment, the method further comprises introducing a mold material, in particular a reflective mold material, into the gap between the reflective encapsulation material and the light conversion layer. The encapsulation material can serve as a reflector, which further increases the efficiency of the optoelectronic device.

According to at least one embodiment, the method further comprises planarizing at least the light conversion layer, and optionally also the reflective encapsulation material and the reflective mold material.

According to at least one embodiment, the step of forming the light conversion layer comprises sedimenting light conversion particles within the light conversion layer so that the light conversion layer has an increasing concentration gradient of light conversion particles arranged in the light conversion layer from a top surface of the light conversion layer towards the light-emitting device.

A method of manufacturing an optoelectronic device is also proposed. The method comprises the following steps:

Providing a carrier substrate with at least one light-emitting component arranged thereon;

Encapsulating the at least one light-emitting component on the carrier substrate with a reflective encapsulation material in such a way that

the at least one light-emitting component is surrounded in the lateral direction by the reflective encapsulation material,

the reflective encapsulation material projects vertically beyond the at least one light-emitting component, and

the reflective encapsulation material forms a cavity above a light-emitting surface of the at least one light-emitting component which has a bottom lying in the same plane as the light-emitting surface;

Determining the position of the light-emitting surface of the at least one light-emitting component relative to the cavity formed;

Arranging and structuring a photosensitive material in the cavity such that an opening of the photosensitive material is substantially congruent with the light-emitting surface in a plan view of the light-emitting surface; and

Creating a light conversion layer on the light-emitting surface in the aperture of the photosensitive material;

wherein the formed cavity comprises side surfaces that are at least partially spaced apart from the light conversion layer; and

wherein a gap between the light conversion layer and the reflective encapsulation material is filled with the photosensitive material during the formation of the light conversion layer.

Possible advantages that can result from the optoelectronic device are:

The process flow can be realized on a lead frame as well as on printed circuit boards, ceramic substrates or other substrates;

A conversion rate of the conversion layer is not dependent on the height of the light-emitting chip;

The back of the carrier substrate is accessible during the entire process chain so that each chip can be contacted electrically, e.g. for color location control;

Different chips and thus different optoelectronic devices are individually adaptable with regard to the amount of light conversion particles in the light conversion layer, i.e. adaptable to a (known) wavelength;

Individually adjustable quantity of light conversion particles in combination with the continuous operability of the chip means that the color location of the converted light can be individually determined and controlled during production;

The conversion layer is not stressed by high-temperature processes such as wire bonding or thermocompression bonding processes;

An epi-near dense phosphor packing, for example by sedimentation of the light conversion particles in the light conversion layer;

An exact alignment of the conversion layer in relation to the light-emitting surface;

No adhesive between light conversion layer and chip or light-emitting surface;

The conversion layer is not subjected to mechanical pressure during the manufacture of the optoelectronic device;

A hard package (mold compound) due to the encapsulation with the reflective encapsulation material;

A possible bonding wire is completely embedded in the hard encapsulation material and thus protected;

The optoelectronic device can be ground over without risking changes in color location and without having to grind fluorescent grains (risk of chipping);

The contrast of the light emission of the optoelectronic device can be optimized by using reflective encapsulation material, e.g. TiO₂ silicone, in the gaps between the conversion layer and the reflective encapsulation material;

The optoelectronic device can include chips with top contact or rear contacts (e.g. flip chip);

Can be realized in various designs and substrate types.

### BRIEF DESCRIPTION OF THE DRAWINGS

In the following, embodiments of the invention are explained in more detail with reference to the accompanying drawings.

FIG. 1A to 1K show steps of a method for manufacturing an optoelectronic device;

FIG. 2A to 2N show steps of a further method for manufacturing an optoelectronic device; and

FIG. 3A to 3M show steps of a further method for manufacturing an optoelectronic device.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects comprise a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

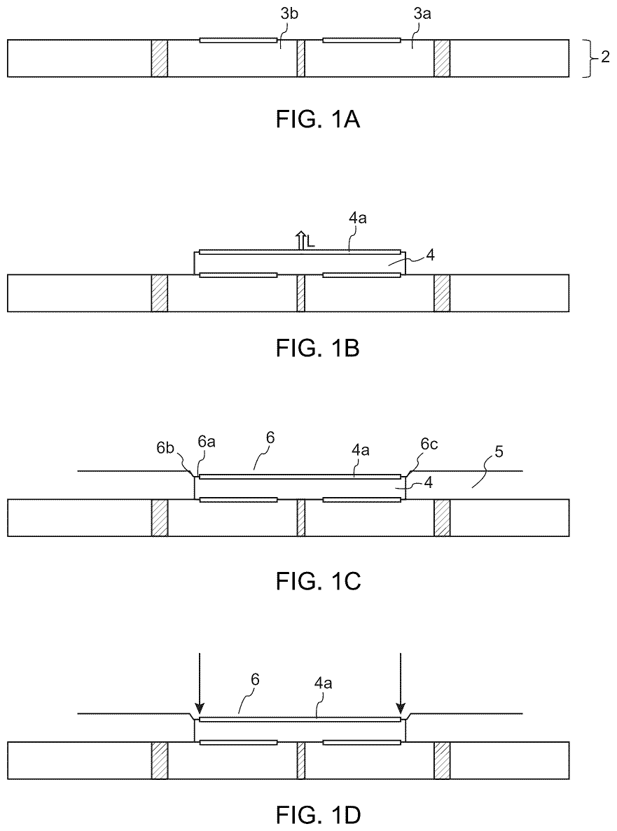

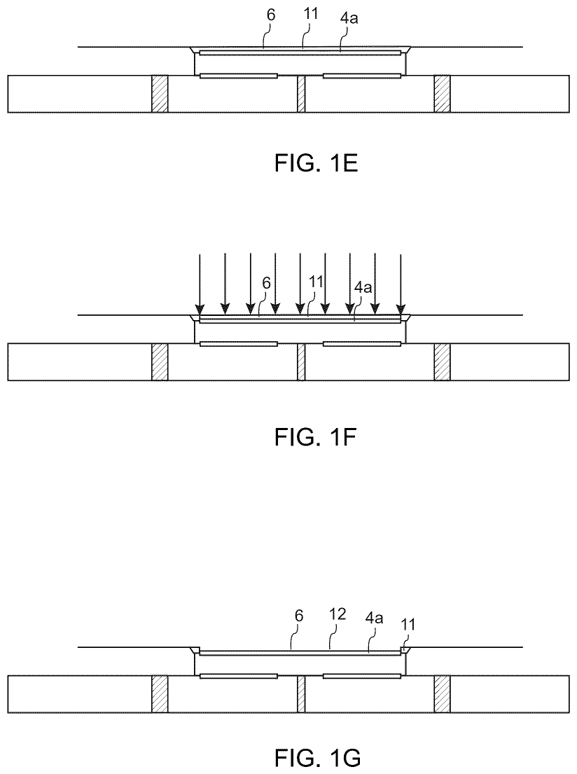

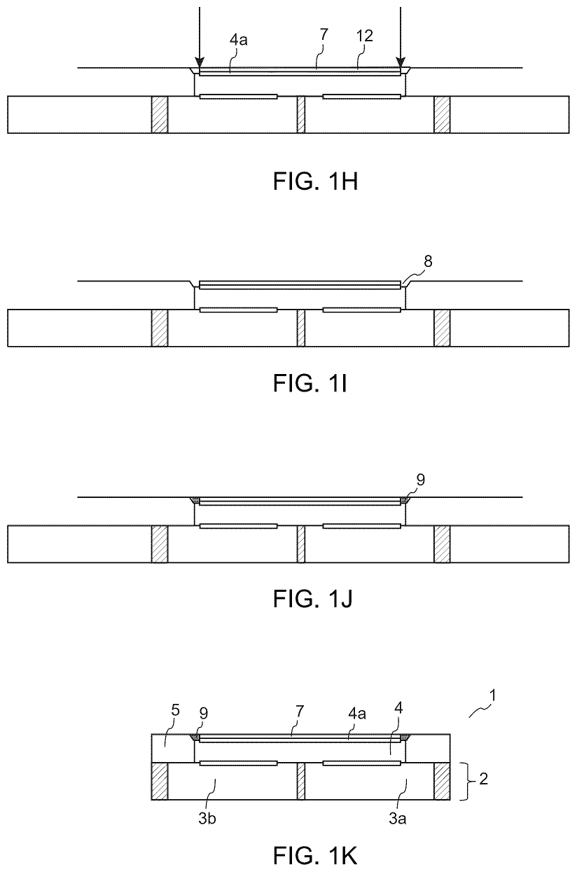

FIGS. 1A to 1K show process steps of a process for manufacturing an optoelectronic device according to some aspects of the proposed principle.

In a first step, as shown in FIG. 1A, a carrier substrate 2 such as a printed circuit board or a lead frame with a first and a second contact region 3a, 3b electrically insulated therefrom is provided for this purpose. A contact pad is provided on each of the first and second contact regions 3a, 3b, to which a light-emitting component 4 in the form of a flip chip is applied in a subsequent step, as shown in FIG. 1B. The light-emitting component 4 comprises a light-emitting surface 4a on a side opposite the electrical connection surfaces of the component and is designed to emit light in the direction of the main emission direction L.

In a further step, as shown in FIG. 1C, the light-emitting component 4 is then encapsulated by means of a reflective encapsulation material 5. In particular, the encapsulation step can be a film-assisted molding, by means of which the light-emitting component 4 is encapsulated in such a way that the light-emitting component 4 is laterally enclosed by the reflective encapsulation material 5, that the reflective encapsulation material 5 projects beyond the light-emitting component 4 in the vertical direction, and that a cavity 6 is formed above the light-emitting surface 4a, so that at least the light-emitting surface 4a remains free of the reflective encapsulation material 5.

The cavity comprises a bottom 6a, which coincides with the light-emitting surface or lies in the same plane as the light-emitting surface. Furthermore, the cavity comprises side surfaces 6b, 6c, which are each arranged at a distance from the respective nearest edges of the light-emitting surface 4a. In the case shown, the light-emitting surface is arranged centrally in the cavity so that the center of gravity of the light-emitting surface and the center of gravity of the bottom of the cavity coincide. However, it is also possible for the cavity or the bottom to be arranged offset from the light-emitting surface 4a.

In particular, the position of the cavity relative to the light-emitting surface can vary from device to device due to manufacturing tolerances and the relatively imprecise manufacturing step for creating the cavity, which is why the cavity is “oversized” as desired in a first step to ensure that the light-emitting surface remains free of the reflective encapsulation material.

In a further step, as shown in FIG. 1D, the exact position of the light-emitting surface 4a relative to the cavity 6 is then determined by means of an optical process (shown by the two arrows). The information thus obtained is then used, as shown in FIGS. 1E to 1G, to structure a photosensitive material 11 (see FIG. 1E) inserted into the cavity 6 in such a way (see the arrows in FIG. 1F) that it comprises an opening 12 (see FIG. 1G) which, in plan view of the light-emitting surface 4a, is substantially congruent with the light-emitting surface 4a. The exact position of the light-emitting surface 4a relative to the carrier substrate 2 can also be determined at an earlier point in time, for example after the light-emitting component 4 has been positioned on the carrier substrate 2.

By introducing and structuring the photosensitive material 11 in the cavity 6 and by creating the opening 12 in the photosensitive material 11, the relatively imprecisely manufactured cavity 6 is reduced in size by means of a relatively precisely adjustable process. This makes it possible to create an opening 12 that is essentially congruent with the light-emitting surface 4a and that can be created individually at the corresponding position for different positions of the light-emitting surface 4a.

In a further step, as shown in FIG. 1H, a light-converting material can be introduced into the now very precisely positioned opening 12 to produce a light conversion layer 7. Due to the very precisely positioned opening 12, it is thus possible in a simple manner to dimension and form the light conversion layer 7 in such a way that it is arranged very close, precisely and without an adhesive joint over the light-emitting surface 4a and does not protrude beyond it.

After the light conversion layer 7 has hardened, the remaining photosensitive material 11 in the gap 8 between the light conversion layer 7 and the reflective encapsulation material 5, as shown in FIG. 1I, can be removed. The gap 8 can now remain free of any material, or it can be filled with a mold material 9, in particular a reflective mold material, as shown in FIG. 1J.

The optoelectronic device 1 is then detached from the composite by separating, for example by sawing through the carrier substrate 2 and the encapsulation material 5, as shown in FIG. 1K. As an example, only the production of an optoelectronic device 1 is shown in steps 1A to 1K, but it is understood that several optoelectronic devices 1 can also be produced simultaneously on the same carrier substrate 2 by means of the method described, which are then separated by a separating step, as shown in FIG. 1K.

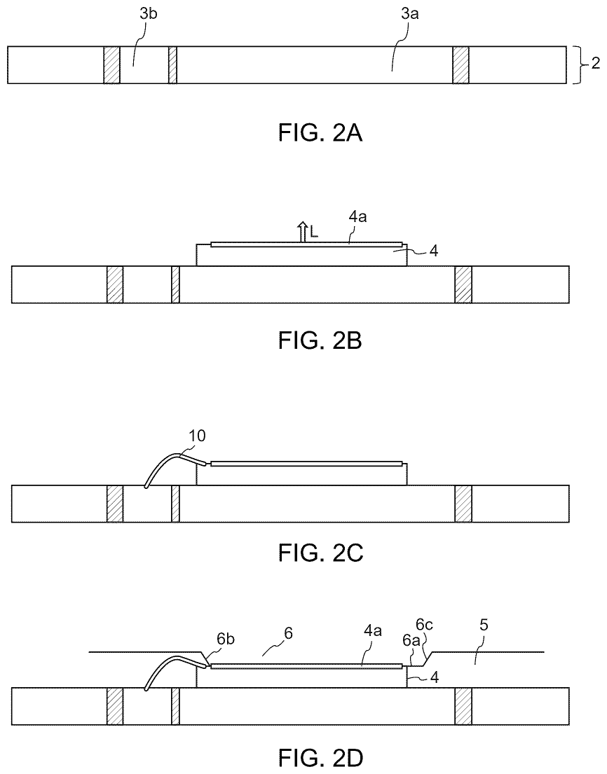

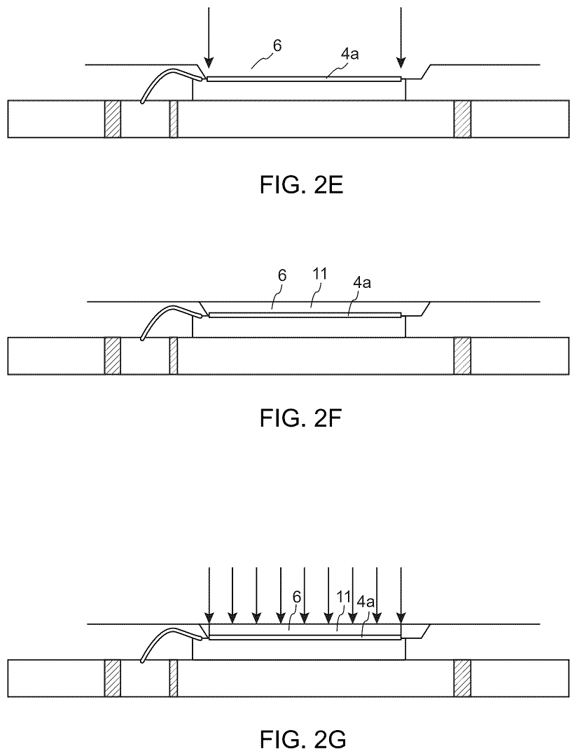

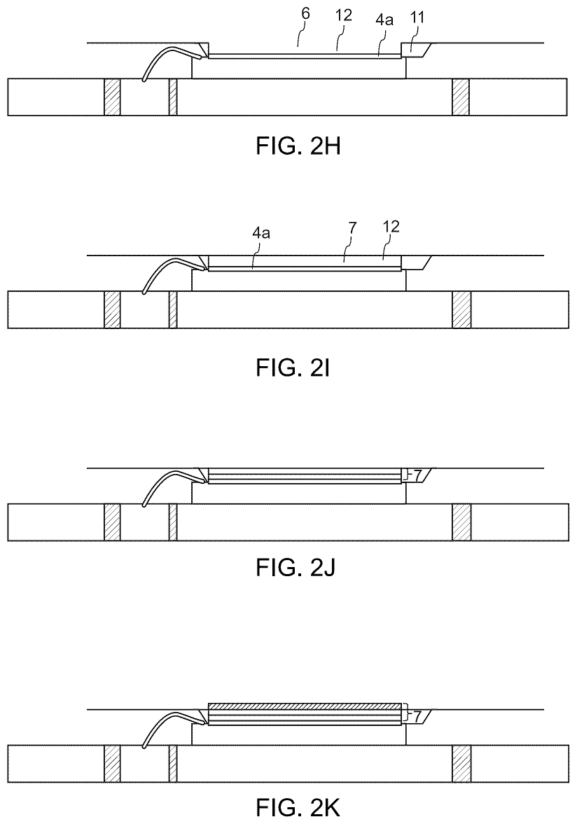

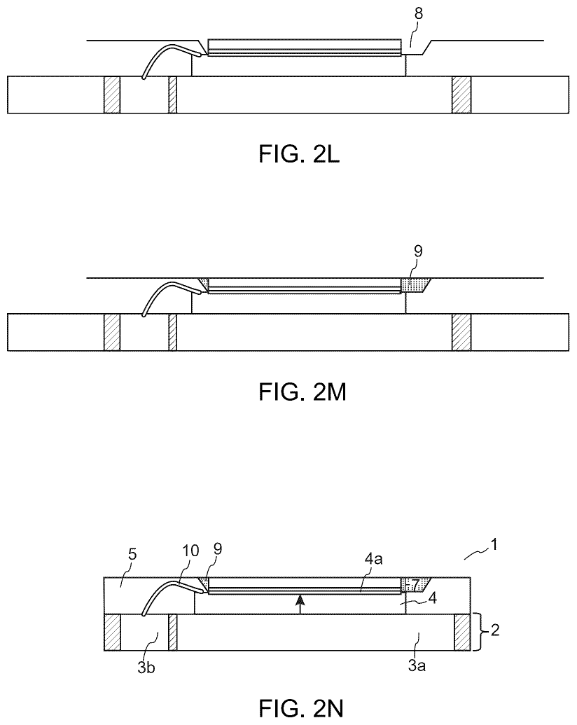

FIGS. 2A to 2N show process steps of a further process for manufacturing an optoelectronic device according to some aspects of the proposed principle.

In contrast to the steps shown in FIGS. 1A to 1K, however, a light-emitting component 4 in the form of a top contact chip is arranged on the carrier substrate 2, as shown in FIGS. 2A and 2B, on the first contact region 3a and electrically connected to the second contact region 3b by means of a bonding wire 10.

The bonding wire also results in the reflective encapsulation material 5, as shown in FIG. 2D, having a greater height, as the reflective encapsulation material 5 is also used to encapsulate the bonding wire 10 in order to protect it from external influences. Compared to the step shown in FIG. 1C, this also results in the cavity 6 having a greater depth. In addition, the bonding wire 10 or the position of the bonding wire 10, as shown in FIG. 2D, can result in the cavity 6 being arranged off-center with respect to the light-emitting surface 4a, so that side surfaces 6a, 6c of the cavity 6 comprise a different distance to a respective nearest edge of the light-emitting surface 4a.

The steps of FIGS. 2E to 2H can then be carried out according to the steps described in FIGS. 1D to 1G.

However, due to the greater depth of the cavity, the formation of the light conversion layer 7 as described for FIG. 1H may further comprise sedimentation of light conversion particles within the light conversion layer 7 so that the light conversion layer 7 has an increasing concentration gradient of light conversion particles arranged in the light conversion layer from a top surface of the light conversion layer toward the light-emitting component 4. Such an embodiment is to be indicated by the two regions of the light conversion layer in FIG. 2J, wherein the region of the conversion layer 7 which is adjacent to the light-emitting surface 4a comprises a higher concentration of light conversion particles than the overlying region. The light conversion layer 7 shown in FIG. 2I, on the other hand, has only one area in which the light conversion particles are homogeneously distributed.

When the light conversion layer 7 is created, it may also protrude over the reflective encapsulation material 5 (shown by the hatched area in FIG. 2K). This may be desirable, but it may also be desirable to remove the protruding area by grinding it off. In the event that it is desired to grind off the protruding area of the light conversion layer, it may be preferable that by sedimenting the light conversion particles in the light conversion layer 7, the light conversion particles are increasingly arranged in the area of the conversion layer 7 that is adjacent to the light-emitting surface 4a, and thus the light conversion layer is not damaged by grinding it off or its properties are changed.

The steps of FIGS. 2L to 2N can then be carried out according to the steps described in FIGS. 1I to 1K.

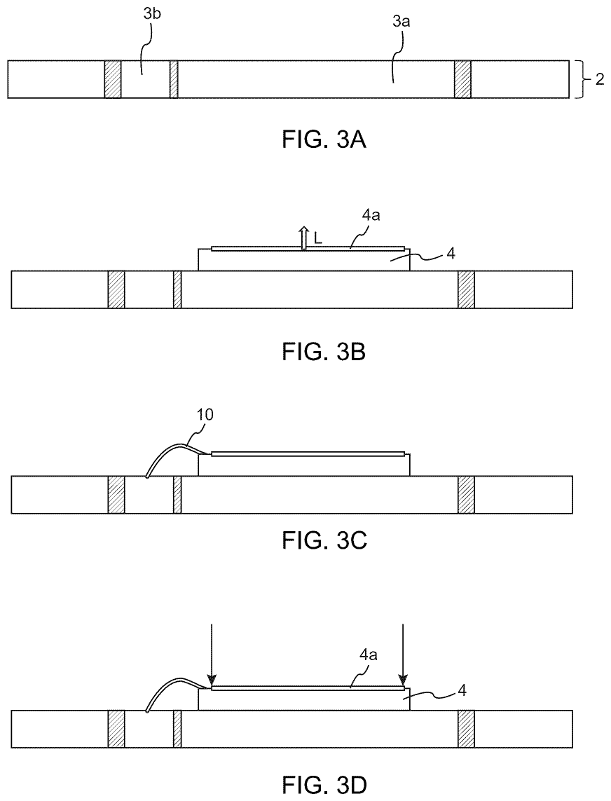

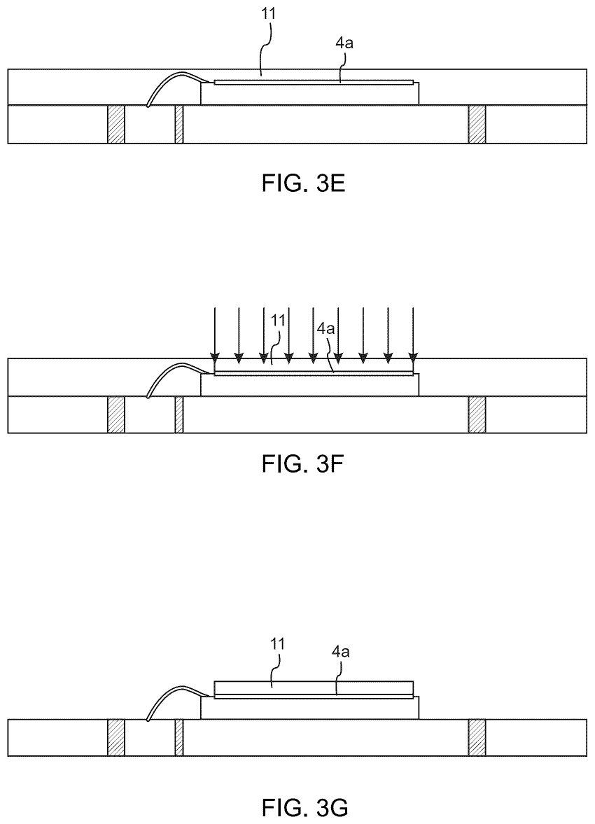

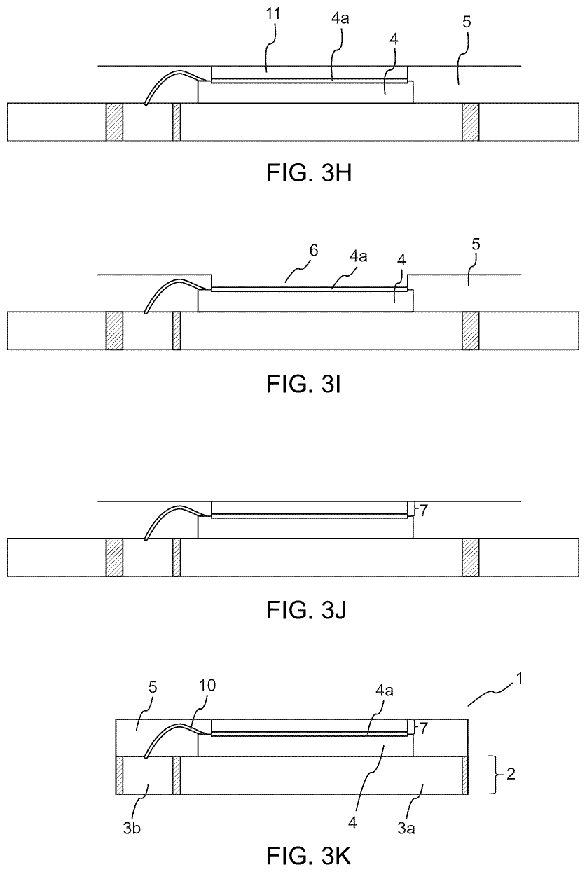

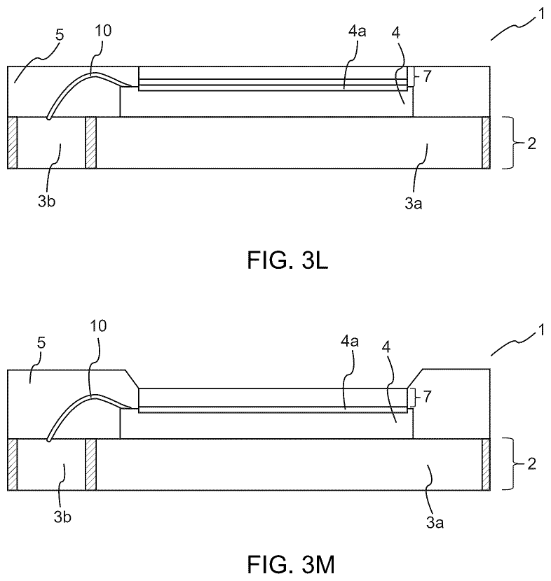

FIGS. 3A to 3M show process steps of a further process for manufacturing an optoelectronic device according to some aspects of the proposed principle.

Compared to the steps shown in FIGS. 1A to 1K and 2A to 2K, the creation of a positionally accurate cavity or opening for creating the positionally accurate light conversion layer, which is essentially congruent with the light-emitting surface of the light-emitting component, takes place in a slightly modified form.

The photosensitive material is used in the form of a kinematic inversion, so to speak, not as a positive form for the positionally accurate cavity or opening, but as a negative form for creating the positionally accurate cavity or opening in the reflective encapsulation material.

In a first step, as shown in FIG. 3A, a carrier substrate 2 such as a printed circuit board or a lead frame with a first and a second contact region 3a, 3b electrically insulated therefrom is provided. As shown in FIG. 3B, a light-emitting component 4 in the form of a top contact chip is placed on the first contact region 3a on the carrier substrate 2 and, as shown in FIG. 3C, is electrically connected to the second contact region 3b by means of a bonding wire 10.

In a further step, as shown in FIG. 3D, the exact position of the light-emitting surface 4a relative to the carrier substrate 2 is then determined by means of an optical method (shown by the two arrows). The information thus obtained is then used, as shown in FIGS. 3E to 3G, to structure a photosensitive material 11 (see FIG. 3E) applied to the light-emitting component 4 and the carrier substrate 2 in such a way (see the arrows in FIG. 3F) that the photosensitive material 11 remains only on an area of the light-emitting component 4 which, in plan view of the light-emitting surface 4a, is substantially congruent with the light-emitting surface 4a (see FIG. 3G).

In a further step, as shown in FIG. 3H, the light-emitting component 4 and the photosensitive material 11 are then encapsulated by means of a reflective encapsulation material 5. The encapsulation step can be a film-assisted molding, for example, by means of which the light-emitting component 4 is encapsulated. The light-emitting component 4 and the photosensitive material 11 are encapsulated in such a way that the light-emitting component 4 and the photosensitive material 11 are laterally enclosed by the reflective encapsulation material 5, and that the reflective encapsulation material 5 projects beyond the light-emitting component 4 in the vertical direction and is at least flush with the photosensitive material 11.

The photosensitive material 11 is then removed, as shown in FIG. 3I, so that a precisely positioned cavity 6 is formed in the reflective encapsulation material 5 above the light-emitting surface 4a, which is filled with a conversion material in a further step, as shown in FIG. 3J, so that the conversion layer 7 is formed. Due to the very precisely positioned cavity 6, it is thus possible to easily dimension and form the light conversion layer 7 in such a way that it is arranged very close, precisely and without an adhesive joint above the light-emitting surface 4a and does not protrude beyond it.

The optoelectronic device 1 is then detached from the composite by separating, for example by sawing through the carrier substrate 2 and the encapsulation material 5, as shown in FIG. 3K. By way of example, steps 3A to 3K only show the production of one optoelectronic device 1, but it is understood that the method described can also be used to simultaneously produce several optoelectronic devices 1 on the same carrier substrate 2, which are then separated by a separation step, as shown in FIG. 3K.

FIGS. 3L and 3M show further embodiments of an optoelectronic device 1 manufactured in this way.

The light conversion layer 7 or the fabrication of the optoelectronic device 1, as shown in FIG. 3L, may further comprise sedimenting light conversion particles within the light conversion layer 7 so that the light conversion layer 7 has an increasing concentration gradient of light conversion particles arranged in the light conversion layer from a top surface of the light conversion layer toward the light-emitting component 4. This is to be indicated by the two regions of the light conversion layer in FIG. 3L, wherein the region of the conversion layer 7 which is adjacent to the light-emitting surface 4a comprises a higher concentration of light conversion particles than the region located above it.

According to the embodiment shown in FIG. 3M, the step of encapsulating the light-emitting component 4 and the photosensitive material 11 by means of the reflective encapsulation material 5 is carried out in such a way that the reflective encapsulation material 5 protrudes above the light-emitting component 4 in the vertical direction and a cavity is formed above the photosensitive material. Using an appropriately structured tool for encapsulating the chip, the cavity can be formed above the photosensitive material in such a way that the encapsulation material protrudes above the chip and the photosensitive material in the vertical direction and a cavity is formed above the photosensitive material, which at least exposes the photosensitive material.

1.-16. (canceled)

17. An optoelectronic device comprising:
a carrier substrate with a first contact region and therefrom electrically insulated a second contact region;
a light-emitting component arranged on the carrier substrate and electrically coupled to the first and second contact regions;
a reflective encapsulation arranged on the carrier substrate,
wherein the reflective encapsulation surrounds the light-emitting component in a lateral direction, protrudes the light-emitting component in a vertical direction, and forms a cavity above a light-emitting surface of the light-emitting component; and
a light conversion layer arranged directly on the light-emitting component in the cavity,
wherein the light-emitting surface is smaller than a top surface of the light-emitting component and extends over part of the top surface of the light-emitting component,
wherein the light conversion layer is substantially congruent with the light-emitting surface in a plan view of the light-emitting surface,
wherein the cavity comprises a bottom lying in the same plane as the light-emitting surface, and
wherein the cavity comprises side surfaces which are arranged at least partially at a distance from the light conversion layer so that a gap exists between the light conversion layer and the reflective encapsulation.

18. The optoelectronic device according to claim 17, wherein the bottom of the cavity is larger than the light-emitting surface in a top view of the light-emitting surface.

19. The optoelectronic device according to claim 17, wherein a distance from a first side surface of the cavity towards a first edge of the light-emitting surface closest to the first side surface is greater than a distance from a second side surface of the cavity towards a second edge of the light-emitting surface closest to the second side surface.

20. The optoelectronic device according to claim 17, wherein a distance between opposite side surfaces of the cavity decreases from a side of the reflective encapsulation opposite the carrier substrate towards the bottom of the cavity.

21. The optoelectronic device according to claim 17, further comprising a mold material arranged in the gap between the reflective encapsulation and the light conversion layer in the cavity and filling the gap.

22. The optoelectronic device according to claim 17, wherein a top surface of the light conversion layer is substantially flush with a side of the reflective encapsulation opposite the carrier substrate.

23. The optoelectronic device according to claim 17, wherein the light conversion layer comprises an increasing concentration gradient of light conversion particles arranged in the light conversion layer from a top surface of the light conversion layer towards the light-emitting component.

24. The optoelectronic device according to claim 17, wherein the light-emitting component is electrically coupled to the second contact region by a bonding wire, and wherein the bonding wire is completely enclosed by the reflective encapsulation.

25. A method for manufacturing an optoelectronic device, the method comprising:
providing a carrier substrate with at least one light-emitting component arranged thereon which comprises a light-emitting surface;
determining a position of the light-emitting surface;
arranging and structuring a photosensitive material such that an opening in the photosensitive material is formed substantially congruently with the light-emitting surface in a plan view of the light-emitting surface, or that the photosensitive material is formed substantially congruently with the light-emitting surface on the light-emitting surface in a plan view of the light-emitting surface;
encapsulating the at least one light-emitting component on the carrier substrate with a reflective encapsulation material such that the at least one light-emitting component is surrounded in a lateral direction by the reflective encapsulation material,
wherein the reflective encapsulation material protrudes above the at least one light-emitting component in a vertical direction, and
wherein the reflective encapsulation material forms a cavity above the light-emitting surface of the at least one light-emitting component, which comprises a bottom lying in the same plane as the light-emitting surface; and
creating a light conversion layer in the cavity on the light-emitting surface such that the light conversion layer is substantially congruent with the light-emitting surface on the light-emitting surface in a plan view of the light-emitting surface.

26. The method according to claim 25, further comprising removing the photosensitive material after the at least one light-emitting component has been encapsulated on the carrier substrate with the reflective encapsulating material, wherein creating the light conversion layer is conducted after removing the photosensitive material.

27. The method according to claim 25, wherein arranging and structuring the photosensitive material is conducted after encapsulating the at least one light-emitting component in the cavity, and wherein the light conversion layer is created in the opening.

28. The method according to claim 27, wherein the cavity comprises side surfaces which are arranged at least partially spaced apart from the light conversion layer and a gap between the light conversion layer and the reflective encapsulation material is filled with the photosensitive material.

29. The method according to claim 28, further comprising removing the photosensitive material in the gap.

30. The method according to claim 29, further comprising introducing a mold material into the gap.

31. The method according to claim 25, further comprising planarizing at least the light conversion layer.

32. The method according to claim 25, wherein creating the light conversion layer comprises sedimenting light conversion particles within the light conversion layer such that the light conversion layer comprises an increasing concentration gradient of light conversion particles arranged in the light conversion layer from a top surface of the light conversion layer towards the light-emitting component.
